(19) United States
(12) Patent Application Publication
(10) Pub. No.: US 2025/0060394 A1
(43) Pub. Date: Feb. 20, 2025

(54) SELF-CALIBRATING CURRENT SENSOR PACKAGE

(71) Applicant: Infineon Technologies AG, Neubiberg, DE (US)

(72) Inventors: Simone FONTANESI, Villach (AT); Gaetano FORMATO, Villach (AT)

(21) Appl. No.: 18/793,258

(22) Filed: Aug. 2, 2024

(30) Foreign Application Priority Data
Aug. 17, 2023 (DE) 102023122076.4

(51) Int. Cl. G01R 19/25; G01R 15/20; G01R 35/00

(52) U.S. Cl. CPC G01R 19/25; G01R 15/207; G01R 35/005

(57) ABSTRACT

The present disclosure proposes a current sensor package with self-calibration functionality. No external microcontroller is needed. The current sensor package includes an integrated current sensor circuit configured to generate an analog sensor signal in response to an electrical current. The current sensor package includes an ADC coupled to the integrated current sensor circuit and configured to convert the analog sensor signal to a digital sensor signal. The current sensor package includes a digital processor coupled to the ADC and configured to implement/run a calibration procedure for the integrated current sensor circuit based on the digital sensor signal and predefined target values. The current sensor package includes a non-volatile memory coupled to the digital processor and configured to store the predefined target values and calibration parameters found during the calibration procedure.

### CROSS-REFERENCE TO RELATED APPLICATION

This application claims priority to Germany Patent Application No. 102023122076.4 filed on Aug. 17, 2023, the content of which is incorporated by reference herein in its entirety.

### TECHNICAL FIELD

The present disclosure relates to current sensors, and, more particularly, to the calibration of integrated current sensors.

### BACKGROUND

A current sensor is an electronic device that measures an amount of AC and/or DC current flowing through a conductor. Current sensors may be used in a wide range of applications, including power electronics, motor control, energy management systems, and industrial automation. They may provide information about the behavior of electrical systems, allowing to monitor, control, and optimize the performance of these systems.

Integrated current sensors may be more compact, efficient, and cost-effective than discrete sensors, since they eliminate the need for discrete circuit components and may simplify the design of the electronic system. Additionally, integrated current sensors may offer features such as programmable gain and bandwidth, temperature compensation, and digital output signals that can be easily interfaced with other electronic components, such as microcontrollers.

A coreless current sensor is a type of current sensor that measures the amount of electrical current flowing through a conductor without the use of a magnetic core. Instead of using a core, coreless current sensors may rely on the principles of the Hall effect, magnetic induction, or any kind of magneto-resistance, like TMR (Tunneling-Magneto-Resistance) to detect the presence of current. Coreless current sensors may be smaller and lighter than their traditional counterparts, which can make them more suitable for applications where space and weight are at a premium. Additionally, coreless current sensors may be more precise and have a faster response time than traditional sensors. There are several types of coreless current sensors available, including Hall effect sensors, fluxgate sensors, and magnetoresistive sensors. Hall effect sensors use a magnetic field to detect the presence of current, while fluxgate sensors use a coil to measure changes in magnetic flux. Magnetoresistive sensors, on the other hand, use changes in the resistance of a magnetic material to measure changes in magnetic field strength.

Current sensors typically provide an output signal that is proportional to the amount of current being measured. This signal can be in the form of a voltage, current, or frequency output, depending on the type of sensor and the application.

Current sensors may have an initial offset and initial sensitivity error due to part-to-part variations coming from manufacturing steps. In addition, current sensors may be subject to errors due to mechanical displacements and manufacturing tolerances, making the overall initial offset and sensitivity errors even more significant. For this reason, an EOL (End-of-line) in-system calibration is typically necessary.

EOL calibration is a type of calibration process that may be performed during or after the manufacturing of a current sensor to ensure that the sensor's output is within its specified accuracy limits. EOL calibration typically involves testing the sensor's output against a known reference current source at various points throughout the sensor's operating range. Any differences between the sensor's output and a reference current may be recorded and adjustments may be made to the sensor's circuitry to bring its output signal into agreement with the reference current. The calibration process may involve adjusting the gain, offset, or linearity of the sensor's output, depending on the type and design of the sensor. Further, it may be important to calibrate current sensors periodically to ensure that they continue to provide accurate and reliable measurements over time. The frequency of calibration depends on factors such as the type of sensor, the operating environment, and the criticality of the measurements being taken.

An exact process for end-of-line (EOL) calibration of a current sensor may vary depending on the specific type of sensor and its manufacturer. However, a typical EOL calibration process for a current sensor may involve the following acts:
Set up a test system: The current sensor is connected to an external test system that includes a known reference current source, as well as any necessary external instrumentation for measuring and recording the sensor's output signal.
Apply test currents: The reference current source is used to apply a range of test currents to the sensor, covering at least a portion of the operating range of the sensor.
Record sensor output: The sensor's output signal is measured and recorded for each test current applied.
Compare to reference: The recorded sensor output signals are compared to the known reference currents, and any differences between the sensor's output and the reference are calculated and recorded.
Adjust sensor output: Based on the recorded differences between the sensor's output and the reference, adjustments may be made to the sensor's circuitry or to its output to bring its output signal into agreement with the reference current.

Conventionally, calibration parameters may be measured and stored either in a microcontroller or directly in the sensor EEPROM at EOL through a digital interface between sensor and the microcontroller. Thus, a user needs to implement a sensor digital communication interface and calibration coefficient calculation, which results in additional time and effort.

Thus, there is a need for an improved concept for calibrating integrated current sensors.

### SUMMARY

This need is met by current sensor packages and methods in accordance with the appended claims.

According to a first aspect, the present disclosure proposes a current sensor package. The current sensor package includes an integrated current sensor circuit which is configured to generate an analog sensor signal in response to an electrical current. The current sensor package further includes an analog-to-digital convertor (ADC) which is coupled to the integrated current sensor circuit and configured to convert the analog sensor signal to a digital sensor signal. The current sensor package further includes a digital processor which is coupled to the ADC and configured to run a calibration procedure for the integrated current sensor circuit based on the digital sensor signal and predefined target values. The current sensor package further includes a non-volatile memory which is coupled to the digital processor and configured to store the predefined target values and calibration parameters found during the calibration procedure.

According to implementations of the present disclosure, a current sensor calibration routine may be implemented directly in the current sensor package which may provide a protective and functional housing for one or more semiconductor dies implementing the circuit components in the current sensor package. In this way the user is not forced to implement the calibration logic in an external microcontroller. The current sensor package including at least the integrated ADC coupled to an AOUT (analog output) of the current sensor package, an integrated non-volatile memory where calibration parameters for sensitivity and offset may be stored, and an integrated digital core implementing the calibration algorithm.

In some implementations, the integrated current sensor circuit of the current sensor package includes a sensing element and signal conditioning circuitry configured to process an analog output signal from the sensing element. The sensing element may include a coil, a magneto-resistor, or a Hall effect sensor. The signal conditioning circuitry may include an amplifier configured to amplify the analog output signal from the sensing element.

In some implementations, the ADC in the current sensor package has a bit-width of at least 6 bits. In this way, a quantization error for analog-to-digital conversion of the analog output signal from the sensing element may be kept low.

In some implementations, the digital processor in the current sensor package is configured to start the calibration procedure if at least one terminal or pin of the current sensor package is set to a predefined state for a predefined time. The predefined state may correspond to a predefined voltage, for example.

In some implementations, the digital processor in the current sensor package is configured to determine, during the calibration procedure, an offset value of the integrated current sensor circuit, and a sensitivity value of the integrated current sensor circuit based on a predefined electrical current, the digital sensor signal in response to the predefined electrical current, and the offset value. The offset value can be caused by a variety of factors, including temperature variation, magnetic interference, manufacturing variation, electrical noise, aging and degradation, or mechanical stress. The sensitivity of a current sensor may be influenced by several factors, including a distance between the current-carrying conductor and the sensor, a frequency of the current being measured, ambient temperature, or electrical noise.

In some implementations, the non-volatile memory in the current sensor package is configured to store one or more correction factors needed to obtain a target sensitivity and a target offset of the integrated current sensor circuit. The non-volatile memory may include an EEPROM (Electrically Erasable Programmable Read-Only Memory) that can be programmed and erased electrically.

In some implementations, the integrated current sensor circuit, the ADC, the digital processor, and non-volatile memory are all integrated on a common semiconductor substrate/semiconductor die. That is, the current sensor package may house a semiconductor die integrating the current sensor circuit, the ADC, the digital processor, and the non-volatile memory.

In some implementations, the current sensor package may further including a current rail integrated into the current sensor package. That is, the current sensor package may include either an integrated current rail in the package for low currents or measure the magnetic field of an external current rail for medium to high currents.

According to a further aspect, the present disclosure also proposes a method for calibrating a current sensor package. The method includes generating, using a current sensor circuit integrated into the current sensor package, an analog sensor signal in response to an electrical current, converting the analog sensor signal to a digital sensor signal using an ADC integrated into the current sensor package, running, on a digital processor integrated into the current sensor package, a calibration procedure for the integrated current sensor circuit based on the digital sensor signal and predefined target values, and storing the predefined target in values and calibration parameters found during the calibration procedure on a non-volatile memory integrated into the current sensor package.

In some implementations, the method may further include initiating the calibration procedure by setting at least one terminal or pin of the current sensor package to a predefined state (e.g., predefined voltage) for a predefined time.

In some implementations, running the calibration procedure in the digital processor includes, within a predefined time window from initiating the calibration procedure, measuring an offset value of the integrated current sensor circuit assuming that there is no electrical current in a measurement path.

In some implementations, running the calibration procedure in the digital processor includes, after the predefined time window from initiating the calibration procedure, forcing a predefined test current in the measurement path, and calculating a sensitivity value of the integrated current sensor circuit based on the predefined test current, the digital sensor signal in response to the predefined test current, and the offset value.

In some implementations, running the calibration procedure in the digital processor includes calculating one or more correction factors needed to obtain a target sensitivity and a target offset of the integrated current sensor circuit, and storing the one or more correction factors in the non-volatile memory.

Thus, implementations of the present disclosure propose a current sensor calibration concept where the sensor itself automatically corrects sensitivity and offset according to target sensitivity and target offset needed by the system.

### BRIEF DESCRIPTION OF THE DRAWINGS

Some examples of apparatuses and/or methods will be described in the following by way of example only, and with reference to the accompanying figures, in which:

FIG. 1 shows a block diagram of a current sensor package with self-calibration capability, in accordance with the present disclosure; and

FIG. 2 shows a flowchart of a self-calibration method for a current sensor package, in accordance with the present disclosure.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Electric current is an important physical quantity and its measurement is required in many applications, be it in industrial, automotive or household fields. Different technical solutions to measure currents are known. Due to galvanic isolation between a sensed circuit and a measuring circuitry, current sensing using Hall effect ICs (Integrated Circuits) may be a good choice for many applications.

An electric current generates a magnetic field around a conductor. The direction can be determined with the “right hand rule”. The field strength, given in A/m, is directly proportional to the current and decreases linearly with higher distances according to

$$H = \frac{l}{2 π r} .$$

Using B=μ₀μᵣH, the flux density can then be expressed as

$$B = \frac{{μ}_{0} {μ}_{r} l}{2 π r}$$

where the material permeability μᵣ is nearly unity for air and the free space permeability μ₀=4π·10⁻⁷ Vs/Am is a constant. The flux density can for example conveniently be measured using an integrated Hall effect IC. Other than for a shunt solution, for current measurements using the Hall effect there is no resistor immersed into the primary circuit and accordingly no voltage drop happens nor is there any power lost. The measuring circuit may be completely independent and galvanically separated, the only power consumed is the one from the Hall measurement device.

Since one is interested in obtaining a continuous signal that is proportional to the current, the devices to be used may be so called linear Hall sensors. These devices deliver an output signal which is a linear function of the magnetic flux density passing perpendicularly through its Hall plate. In modern linear Hall ICs, a Hall plate may be integrated together with high precision readout and compensation circuitry on a single piece of silicon.

Although the direct measurement of the magnetic field of a conductor is possible, in practice may be is advisable to use a field concentrator to both concentrate and boost the magnetic flux. Additionally, this soft magnetic concentrator may help to make the setup less prone to mechanical misalignments.

Linear Hall sensors my detect the flux density and the sensor output may be programmable in the form

$$AOUT = S \cdot B + O ,$$

where S is the sensor's sensitivity and O is the offset. Both these parameters are programmable, meaning that any first order transfer function can be chosen (within the parameter range limits) to adapt to a required measurement range. The sensitivity and offset are programmable and therefore allow to calibrate out any spreads due to production spread.

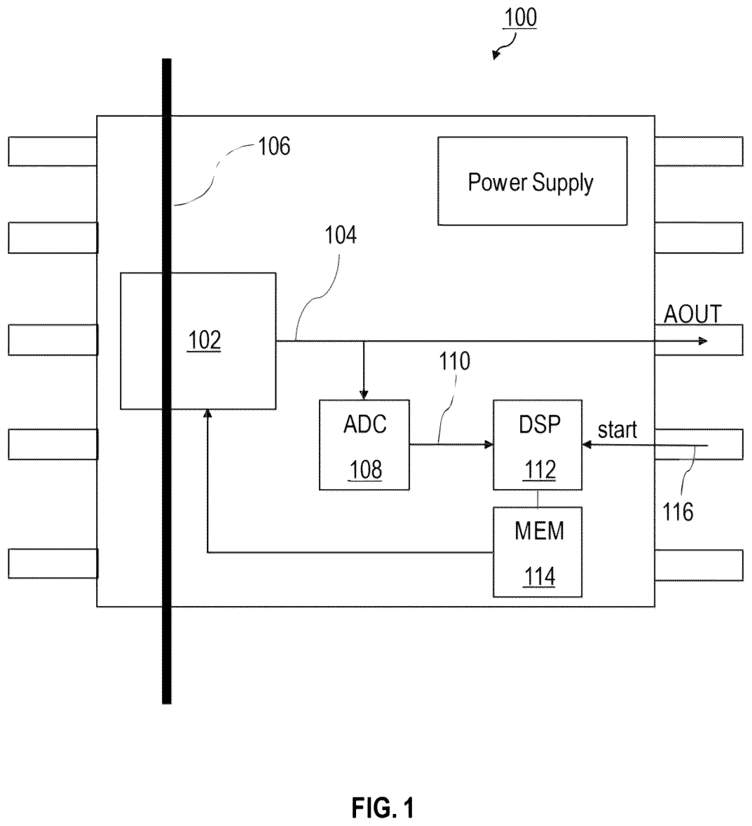

The block diagram of FIG. 1 illustrates, as an illustrative example, a current sensor package 100 in accordance with the present disclosure.

The current sensor package 100 may be an enclosure comprising one or more semiconductor chips or integrated circuits (ICs) and may provide electrical connections (pins) to the outside world. The current sensor package 100 may protect included sensitive semiconductor components from damage, provide mechanical support, and aid in thermal management. The current sensor package 100 may also provide means of mounting the package 100 onto printed circuit boards or other substrates.

The current sensor package 100 comprises an integrated current sensor circuit 102 which is configured to generate an analog sensor signal 104 in response to an electrical current flowing through a current rail 106. The current rail 106 may be external or internal to the current sensor package 100.

The current sensor circuit 102 integrated into the current sensor package 100 may comprise one or more current sensing elements, such as Hall effect sensing elements, inductive sensing elements (coils), one or more magneto-resistive sensing elements, or combinations thereof. A Hall effect sensing element is a type of coreless current sensor that uses the Hall effect to measure the magnetic field generated by the current through the current rail 106. Hall effect sensors may comprise a thin slab of semiconductor material with a current-carrying conductor placed perpendicular to its surface. When a magnetic field is applied, it deflects the flow of electrons in the semiconductor, generating a voltage across the conductor that is proportional to the magnetic field and therefore to the current through the current rail 106. A magneto-resistive sensing element is a type of coreless current sensor that uses a magneto-resistive effect to measure the magnetic field generated by the current through the current rail 106. Magneto-resistive effects are Anisotropic magnetoresistance (AMR), Giant magnetoresistance (GMR), or tunnel magnetoresistance (TMR). A magneto-resistive sensor may comprise a thin layer stack of magnetic and non-magnetic material with a resistance that varies with the applied magnetic field. The current flowing through the current rail 106 generates a magnetic field that is detected by the magneto-resistive element, producing an output signal proportional to the current. It is also conceivable that current sensor circuit 102 comprises an inductive current sensor and uses one or more coils as sensing elements.

Current sensor circuit 102 may comprise additional circuit components in addition to one or more current sensing elements. For example, the integrated current sensor circuit 102 in the current sensor package 100 may comprise signal conditioning circuitry configured to process an analog output signal from the sensing element(s). Signal conditioning circuitry may be circuitry that processes the analog sensor signal from the sensing element(s) to make it suitable for further processing or measurement. The analog sensor signal of the sensing element is typically a low-level voltage or current that is proportional to the measured current. However, this signal may be noisy, have a low signal-to-noise ratio, or be incompatible with input requirements of subsequent circuitry. Therefore, a signal conditioning circuit may be used to improve the quality of the signal and to match it to the needs of the next stage of processing. A specific design of a signal conditioning circuit for a current sensor depends on the type of current sensor and the application requirements. However, some common functions of signal conditioning circuits for current sensors include amplification, filtering, linearization, or conversion (e.g., voltage-to-current conversion, current-to-voltage conversion).

The current sensor package 100 further comprises an ADC 108 which is coupled to the output of integrated current sensor circuit 102 and configured to convert the analog sensor signal 104 to a digital sensor signal 110. ADC 108 may come in various possible implementations. For example, ADC 108 may be a delta-sigma ADC. This type of ADC uses oversampling and noise-shaping techniques to convert the analog signal 104 into the digital sensor signal 110. It may sample the input signal at a very high rate and then filter the resulting digital signal to remove the noise. The ADC 108 in the current sensor package 100 may have a bit-width of at least 6 bits, for example. In this way, a quantization error for analog-to-digital conversion of the analog sensor signal 104 may be kept low.

The current sensor package 100 further comprises a digital processor 112 which is coupled to the output of ADC 108 and configured to implement an automatic calibration procedure for the integrated current sensor circuit 102 based on the digital sensor signal 110 and based on predefined target values (e.g., for sensitivity and offset). For this purpose, current sensor package 100 further comprises a non-volatile memory 114 which is coupled to the digital processor 112 and configured to store the predefined target values and calibration/correction parameters found during the calibration procedure.

Digital processor 112 may be an integrated digital core of the current sensor package 100. It refers to the part of the current sensor package 100 that performs the digital processing and manipulation of data during the calibration procedure. The digital core may be the heart of the current sensor package 100, responsible for executing instructions and performing the computational tasks required for the calibration procedure. It may include a control unit, arithmetic logic unit (ALU), memory, and input/output (I/O) interfaces, depending on the specific application and design. Digital processor 112 may comprise or interface with non-volatile memory 114. Non-volatile memory 114 may be implemented as an EEPROM which can be electrically programmed and erased during the calibration procedure.

The skilled person having benefit from the present disclosure that the current sensor package 100 may include more circuits components than illustrated in FIG. 1. For example, a power supply circuit may provide the necessary power to operate the current sensor package 100. It may include voltage regulators, decoupling capacitors, and other components to ensure stable and reliable operation. An output circuit may provide the output signal of the current sensor package 100, which may be in the form of a voltage or current signal proportional to the input current. The output circuit may include voltage dividers, buffer amplifiers, and other components to provide a stable and reliable output signal.

The integrated current sensor circuit 102, the ADC 108, the digital processor 112, and non-volatile memory 114 may all be integrated on a common semiconductor die. Thus, the current sensor package 100 may house a single semiconductor die integrating the current sensor circuit 102, the ADC 108, the digital processor 112, and the non-volatile memory 114. In such a case, the current sensor package 100 may also be referred to as current sensor IC 100.

Digital processor 112 in the current sensor package 100 may comprise memory storing a program code to execute the self-calibration procedure of the current sensor package 100 when the program code is executed on the digital processor 112. Digital processor 112 may be configured to start the integrated calibration procedure if at least one terminal or pin 116 of the current sensor package is set to a predefined state for a predefined time. The predefined state may correspond to a predefined voltage, such as ground (GND) or a power supply voltage (VDD). The predefined time may correspond to 1s, 2s or 5s, for example.

Digital processor 112 in the current sensor package 100 may be configured to determine, during the self-calibration procedure, an offset value of the integrated current sensor circuit 102 assuming that there is no current in the current rail 106 within a predefined time window from startup time. As mentioned before, the offset value can be caused by a variety of factors, including temperature variation, magnetic interference, manufacturing variation, electrical noise, aging and degradation, or mechanical stress.

Further, during the self-calibration procedure, digital processor 112 in the current sensor package 100 may be configured to determine a sensitivity value of the integrated current sensor circuit 102 based on a predefined electrical test current through the current rail 106 within a predefined time window from startup time. The sensitivity of the current sensor may be influenced by several factors, including a distance between the current-carrying conductor and the sensor, a frequency of the current being measured, ambient temperature, or electrical noise. The sensitivity value may be calculated based on the predefined electrical test current, the digital sensor signal 110 in response to the predefined electrical test current, and the offset value.

The proposed current sensor package 100 with built-in self-calibration may automatically correct sensitivity and offset according to target sensitivity and target offset needed by the system.

In case of external current rails 106, a target sensitivity in [V/A] cannot be chosen by a user because a transfer factor TF [T/A] between the external current rail 106 and the one or more sensing elements must be known. A datasheet has to fix the nominal TFs to be implemented by the user for each sensor gain [V/T]. This is not a problem, instead it reduces the effort on user side since(s) he does not need to design the current rail, but predefined designs are given by a sensor manufacturer.

In case of external current rails 106, the TF [T/A] of the internal current rail is known by design.

The target sensitivity is then defined and known by the sensor package 100:

$$Target sensitivity [ \frac{V}{A} ] = TF [ \frac{T}{A} ] * Sensor gain [ \frac{V}{T} ]$$

The target offset may be zero. The self-calibration procedure may therefore be simplified as follows:
1. Enter the “calibration mode” of digital processor 112 by pulling down pin 116.
2. The digital processor 112 measures the (digital) sensor offset V₀_{_{|I=0}} (analog sensor signal 104) assuming that there is no current in the current rail 106 within a predefined time window from startup time.
3. Force a predefined test current I_{TEST} in the current rail 106 (e.g., <1% error to be negligible with respect to the target accuracy) within a predefined time window from startup time. The value of the test current I_{TEST} may be noted on datasheet and it is different for each sensor gain setting.
4. The digital processor 112 measures the (digital) output pin voltage V_{0|I}_{_{TEST}} (analog sensor signal 104) and calculates the sensitivity, knowing the target test current I_{TEST}

$$Sensitivity = \frac{{V}_{O \vert {I}_{TEST}} - {V}_{O \vert I = 0}}{{I}_{TEST}} .$$

5. The digital processor 112 calculates a correction factor needed to obtain a target sensitivity and target offset and stores the correction factors in the EEPROM 114. The correction factors may then be combined with actual measurement values to generate a calibrated analog sensor signal 104.

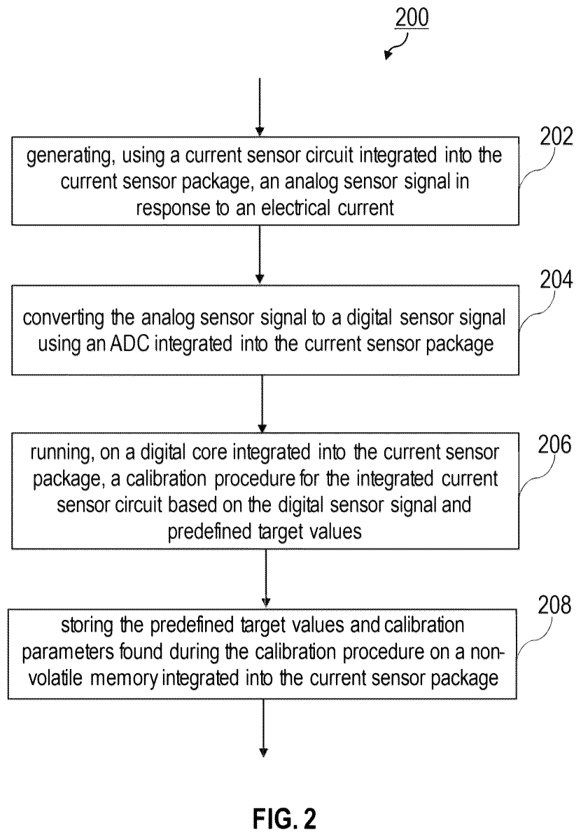

FIG. 2 illustrates a flowchart of a method 200 for self-calibrating the current sensor package 100 without the need for an external microcontroller.

The method 200 includes generating 202, using the current sensor circuit 102 integrated into the current sensor package 100, an analog sensor signal 104 in response to an electrical current in an internal or external current rail 106. The method 200 further includes converting 204 the analog sensor signal 104 to a digital sensor signal 110 using an ADC 108 integrated into the current sensor package 100. The method 200 further includes running 206, on the digital core 112 integrated into the current sensor package 100, a self-calibration procedure using the digital sensor signal and predefined target values for offset and sensitivity. The method 200 further includes storing 208 the predefined target values and calibration parameters found during the calibration procedure on the non-volatile memory 114 integrated into the current sensor package 100.

The self-calibration procedure may be initiated by setting at least one terminal or pin 116 of the current sensor package 100 to a predefined state (e.g., predefined voltage) for a predefined time.

The self-calibration procedure running on the digital core 112 may include, within a predefined time window from initiating the self-calibration procedure, measuring an offset value V₀_{_{|I=0}} of the current sensor assuming that there is no electrical current in the current rail 106.

The self-calibration procedure running on the digital core 112 may include, after the predefined time window from initiating the self-calibration procedure, forcing a predefined test current I_{TEST} in the current rail 106, and calculating a sensitivity value Sensitivity of the current sensor based on the predefined test current I_{TEST}, the digital sensor signal V_{0|I}_{_{TEST}} in response to the predefined test current, and the offset value V_{0|I}_{_{TEST.}}

The self-calibration procedure running on the digital core 112 may include calculating one or more correction factors needed to obtain a target sensitivity and a target offset of the current sensor, and storing the one or more correction factors in the non-volatile memory 114.

An advantage for the user may be that the only requirements for the proposed EOL self-calibration of current sensor package 100 are to force an accurate test current I_{TEST} in the current rail 106 and trigger the sensor calibration mode at EOL of their system. There is no need to implement a dedicated digital interface in an external microcontroller since the calibration mode can be started by pulling down a pin at startup. There is no need to implement the calibration routine in the microcontroller firmware. This is an advantage because it minimizes the effort in the development of the microcontroller firmware and in the modification of the firmware for existing systems.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F) PLAs), (field) programmable gate arrays ((F) PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A current sensor package, comprising:
an integrated current sensor circuit configured to generate an analog sensor signal in response to an electrical current;
an analog-to-digital convertor (ADC) coupled to the integrated current sensor circuit and configured to convert the analog sensor signal to a digital sensor signal;
a digital processor coupled to the ADC and configured to run a calibration procedure for the integrated current sensor circuit based on the digital sensor signal and predefined target values; and
a non-volatile memory coupled to the digital processor and configured to store the predefined target values and calibration parameters determined during the calibration procedure.

2. The current sensor package of claim 1, wherein the integrated current sensor circuit comprises a sensing element and signal conditioning circuitry configured to process an analog output signal received from the sensing element.

3. The current sensor package of claim 1, wherein the integrated current sensor circuit comprises a coil, a magneto-resistor, or a Hall effect sensor.

4. The current sensor package of claim 1, wherein the digital processor is configured to start the calibration procedure if at least one terminal of the current sensor package is set to a predefined state for a predefined time.

5. The current sensor package of claim 1, wherein the digital processor is configured to determine, during the calibration procedure,
an offset value of the integrated current sensor circuit, and
a sensitivity value of the integrated current sensor circuit based on a predefined electrical current, the digital sensor signal in response to the predefined electrical current, and the offset value.

6. The current sensor package of claim 5, wherein the non-volatile memory is configured to store one or more correction factors for determining a target sensitivity and a target offset of the integrated current sensor circuit.

7. The current sensor package of claim 1, wherein the integrated current sensor circuit, the ADC, the digital processor, and the non-volatile memory are integrated on a common semiconductor substrate.

8. The current sensor package of claim 1, wherein the non-volatile memory comprises an EEPROM.

9. The current sensor package of claim 1, further comprising a current rail integrated into the current sensor package.

10. A method for calibrating a current sensor package, the method comprising:
generating, using a current sensor circuit-integrated into the current sensor package, an analog sensor signal in response to an electrical current;
converting the analog sensor signal to a digital sensor signal using an analog-to-digital converter (ADC) integrated into the current sensor package;
running, on a digital processor integrated into the current sensor package, a calibration procedure for the integrated current sensor circuit based on the digital sensor signal and predefined target values; and
storing the predefined target values and calibration parameters determined during the calibration procedure on a non-volatile memory integrated into the current sensor package.

11. The method of claim 10, further comprising:
initiating the calibration procedure by setting at least one terminal of the current sensor package to a predefined state for a predefined time.

12. The method of claim 10, wherein running the calibration procedure comprises:
within a predefined time window from initiating the calibration procedure, measuring an offset value of the integrated current sensor circuit.

13. The method of claim 12, wherein running the calibration procedure comprises:
after the predefined time window from initiating the calibration procedure;
forcing a predefined test current in a measurement path; and
calculating a sensitivity value of the integrated current sensor circuit based on the predefined test current, the digital sensor signal in response to the predefined test current, and the offset value.

14. The method of claim 13, wherein running the calibration procedure comprises:
calculating one or more correction factors for determining a target sensitivity and a target offset of the integrated current sensor circuit; and
storing the one or more correction factors in the non-volatile memory.
